(19) United States
(12) Patent Application Publication
(10) Pub. No.: US 2009/0079497 A1
(43) Pub. Date: Mar. 26, 2009

(54) PHASE TUNING TECHNIQUES

(75) Inventors: Axel Schuur, Mountain View, CA (US); Ann Shen, Saratoga, CA (US)

Correspondence Address: FISH & RICHARDSON P.C., P.O. BOX 1022, MINNEAPOLIS, MN, 55440-1022, US

(73) Assignee: NanoAmp Solutions, Inc. (Cayman), Santa Clara, CA (US)

(21) Appl. No.: 12/114,344

(22) Filed: May 2, 2008

Related U.S. Application Data
(60) Provisional application No. 60/974,112, filed on Sep. 21, 2007.

(51) Int. Cl. H03B 19/12; H03D 3/22

(52) U.S. Cl. 329/307; 327/117; 329/306

(57) ABSTRACT

A differential frequency divider includes first and second input terminals each configured to receive a differential input signal. The divider also includes a first output terminal configured to produce a first output signal and a second output terminal configured to produce a second output signal. The divider further includes a third input terminal coupled to the first output terminal and a fourth input terminal coupled to the second output terminal. In addition, the divider includes a first variable current source. Altering a current of the first variable current source causes a change in the phase difference between a first output signal of the first output terminal and a second output signal of the second output terminal.

### CROSS REFERENCE TO RELATED APPLICATIONS

This application claims the benefit of priority from U.S. Provisional Application entitled “LOCAL OSCILLATOR PHASE TUNING”, Application No. 60/974,112 filed Sep. 21, 2007, the disclosure of which is incorporated by reference.

### TECHNICAL FIELD

This disclosure relates to tuning techniques, for example, phase tuning of a local oscillator signal.

### BACKGROUND

Frequency dividers can be used in integrated communication circuits. In some applications, RF frequency dividers can generate quadrature Local Oscillator (LO) signals used in image-rejecting mixer circuits for frequency up conversion or down conversion. The quality of the image rejection can depend on the phase and amplitude accuracy of the LO. In general, to maximize the quality of image rejection, the phase difference between the in-phase (I) and quadrature (Q) branches of the LO signals at the output of the frequency divider should be close to 90 degrees and their amplitudes should be as equal as possible.

Small parasitic effects can degrade the accuracy of the LO signals. As a result, image rejection can be adversely affected by mismatches in the frequency divider in the oscillator circuit that drives the frequency divider or in the image rejecting mixer circuits that are driven by the LO signals.

### SUMMARY

Generally, implementations can involve tuning the phase difference between the I and the Q output signals of a frequency divider, such as, for example, a radio frequency (RF) frequency divider. In particular, in one implementation, variable tail bias currents for the I and/or Q branches of an RF frequency divider can be used to tune the phase difference between the I and Q outputs. The techniques described here can be compatible with digital algorithms used in communication systems. The techniques set forth in the present disclosure can, for example, provide for more accurate quadrature Local Oscillator (LO) signals in image-rejecting mixer circuits for frequency conversion.

According to one general aspect, a method includes coupling a differential input signal to first and second input terminals of a differential frequency divider. The differential frequency divider includes at least a first variable current source. The method also includes coupling a first output signal connected to a first output terminal of the differential frequency divider to a third input terminal of the differential frequency divider and coupling a second output signal connected to a second output terminal of the differential frequency divider to a fourth input terminal of the differential frequency divider. The method further includes coupling an input terminal of the first variable current source to phase optimization circuitry that is configured to adjust the first variable current source such that a phase difference between first and second output signals of the differential frequency divider is adjusted.

The method can include other features. For example, the first output signal can be an in-phase output signal and the second output signal can be a quadrature output signal or the first output signal can be quadrature output signal and the second output signal can be an in-phase output signal. Coupling the first variable current source to the phase optimization circuitry can include coupling the first variable current source to the phase optimization circuitry such that the rise or fall time of the first output signal is altered by altering a current of the first variable current source. The first variable current source can include one or more transistors or field effect devices that are switched on or off to alter the current of the first variable current source.

Also, the differential frequency divider can include a second variable current source and can couple the second variable current source to the phase optimization circuitry such that the rise or fall time of the second output signal is altered by altering a current of the second variable current source. The phase optimization circuitry can be configured to adjust the first and second variable current sources by altering currents of the first and the second current sources separately or in combination. The second variable current source can include one or more transistors or field effect devices that are switched on or off to alter the second variable current source.

The method can also include coupling a current mirror to the first and second variable current sources and coupling a reference bias current to the current mirror to generate tail bias current sources for tuning the phase differences between the first and second output signals. Each of the variable current sources can include an accelerating input or a each of the variable current sources can include a decelerating input. The accelerating or decelerating inputs can be controlled by the phase optimization circuitry based on the first output signal and the second output signal. The phase optimization circuitry can be configured to adjust the accelerating input and the decelerating input based on the first output signal and the second output signal of the frequency divider. Also, in the method, at least one of the variable current sources can include an accelerating input and a decelerating input.

Further, coupling the input terminal to the phase optimization circuitry can include coupling phase optimization circuitry configured to increase current of the first variable current source. Coupling the input terminal to the phase optimization circuitry can include coupling phase optimization circuitry configured to decrease current of the first variable current source. The differential frequency divider can include a third or higher order divider. Coupling the input terminal to the phase optimization circuitry can include coupling phase optimization circuitry configured to enable tuning of a quadrature phase difference for a quadrature local oscillator signal between the first output signal and the second output signal by adjusting the first variable current source.

Moreover, the method can further include coupling phase tuning information associated with the first and second output terminals of the differential frequency divider to the phase optimization circuitry. Coupling phase tuning information to the phase optimization circuitry can include coupling image rejection information to the phase optimization circuitry. Coupling phase tuning information to the phase optimization circuitry can consists of coupling the first and second output terminals to the phase optimization circuitry.

According to a second general aspect, a differential frequency divider includes first and second input terminals each configured to receive a differential input signal. The divider also includes a first output terminal configured to produce a first output signal and a second output terminal configured to produce a second output signal. The divider further includes a third input terminal coupled to the first output terminal and a fourth input terminal coupled to the second output terminal. In addition, the divider includes a first variable current source. Altering a current of the first variable current source causes a change in the phase difference between a first output signal of the first output terminal and a second output signal of the second output terminal.

The divider can include other features. For example, the first output signal can be an in-phase output signal and the second output signal can be a quadrature output signal. The first output signal can be a quadrature output signal and the second output signal can be an in-phase output signal. The divider can also include phase optimization circuitry, coupled to the first variable current source, configured to tune a phase difference between the first output signal and the second output signal by altering the current of the first variable current source.

The divider can also include a second variable current source. The phase optimization circuitry can be configured to time a phase difference between the first output signal and the second output signal by altering both the currents of the first variable current source and the current of the second variable current source. The phase optimization circuitry can be configured to tune a phase difference between the first and second output signals by altering currents of the first and the second current sources separately or in combination. The phase optimization circuitry can be configured to tune the phase difference based on a measurement of image rejection.

The divider can further include a current mirror coupled to the first and second variable current sources and a reference bias current coupled to the current mirror to generate tail bias current sources for tuning the phase differences between the first and the second output signals. The phase optimization circuitry can be further configured to increase or decrease the current of the first variable current source by switching one or more transistors or field effect devices on and off. Each of the first and the second variable current sources can include a fixed tail bias current source and multiple switched tail bias current sources. Each switched tail bias current source can be weighted to provide a different amount of current. The phase optimization circuitry can include an output coupled to each of the multiple switched tail bias current sources to selectively switch the corresponding switched tail bias current source on and off. Each of the variable current sources can include an accelerating input or each of the variable current sources can include a decelerating input. Alternatively each of the first and the second variable current sources can include a decelerating input. At least one of the variable current sources can include an accelerating input and a decelerating input. The phase optimization circuitry can be configured to adjust the accelerating input and the decelerating input based on an in-phase I output signal and a quadrature-phase Q output signal. The differential frequency divider can include a third or higher order divider.

In addition, the divider can include phase optimization circuitry configured to adjust the first variable current source such that a phase difference between the first and second output signals is adjusted. The phase optimization circuitry can be coupled to phase tuning information associated with the first and second output terminals. The phase tuning information can consist of signals of the first and second output. The phase tuning information can include image rejection information. The first variable current source can include an accelerating input and a decelerating input.

According to a third general aspect, a method of tuning a phase includes dividing an oscillator output signal with a frequency divider and generating a first output signal of the frequency divider. The method also includes generating a second output signal of the frequency divider with a phase different from the first output and measuring the phase difference between the first and the second output signals of the frequency divider. The method further includes generating, based on the measured phase difference between the first and the second output signals, at least one acceleration or deceleration signals, and applying the acceleration or deceleration signal to at least one variable current source in the frequency divider to adjust the phase difference between the first and the second output signals by altering a current of the variable current source.

According to fourth general aspect, a method of tuning a phase, the method includes receiving, as an input signal at an antenna, a radio frequency signal and filtering the received input signal. The method also includes mixing the filtered input signal with a mixer coupled to phase shifted local oscillator output signals and measuring image rejection of the phase shifted outputs of the mixer. The method further includes determining, based on the measured image rejection of the phase shifted outputs of the mixer, to adjust a phase difference of the output signals of the local oscillator and adjusting a tail bias current such that a phase difference of the output signals of the local oscillator, thereby adjusting the outputs of the mixer.

The method can include other features. For example, adjusting the tail bias current can include increasing a tail bias current from a previous current level. Adjusting the tail bias current can include decreasing a tail bias current from a previous current level. Adjusting the tail bias current can include adjusting a tail bias current coupled to an I branch of the local oscillator and adjusting a tail bias current coupled to a Q branch of the local oscillator. The method may also include measuring the image rejection in the digital-signal-processor or in the baseband.

According to a fifth general aspect, a method includes dividing an input signal with at least one differential frequency divider to generate an I output signal and a Q output signal and measuring a phase difference between the I and Q output signals of the differential frequency divider. The method also includes determining, based on the measured phase difference, that the phase difference between the I output signal and a Q output signal is outside of a target magnitude. The method further includes increasing or decreasing a tail current of a variable current source coupled to the differential frequency divider such that the phase difference between the I and the Q output signal is decreased or increased.

According to a sixth general aspect, a system includes a phase-locked loop generating one or more local oscillators with different frequencies and one or more phase shifting and tuning frequency dividers configured to generate quadrature phase shifted and tuned I/Q output signals from the local oscillator outputs. The system also includes a phase optimization circuit configured to tune the phase difference of phase shifted output signals based on feedback of output signals of the frequency divider and an radio frequency (RF) input signal received by an antenna coupled to an RF filter. The system further includes a low noise amplifier (LNA) coupled to an output of the RF filter. In addition, the system includes a first set of I/Q mixers configured to perform image rejection and mix an output of the LNA with a first set of quadrature I/Q output signals tuned by a first frequency divider from an output of a first local oscillator and a set of I/Q IF filters coupled to a first set of mixed I/Q outputs of the first set of IQ mixers. Moreover, the system includes a second set of I/Q mixers configured to mix filtered I/Q outputs of the I/Q intermediate filer (IF) filters with a second set of I/Q outputs generated and tuned by a second frequency divider from an output of a second local oscillator and a second set of mixed I/Q outputs coupled to a digital-signal-processor. Finally, the system includes a digital-signal-processed output coupled to a baseband for further processing.

Particular implementations can provide one or more of the following potential advantages: accuracy in phase generation, tuning, or conversion, power saving, spectral efficiency, data rate improvement, external component reduction and simplicity in circuit design for circuits such as, for example, local oscillators.

Details of one or more implementations are set forth in the accompanying drawings and description herein. Other features, aspects, and advantages will be apparent from the description, the drawings, and the claims.

### DESCRIPTION OF THE DRAWINGS

FIG. 1 is an example schematic of a divide-by-2 circuit with Current-Mode Logic topology.

FIG. 2 is an example schematic of a divide-by-2 circuit with variable tail bias current sources.

FIGS. 3A-FIG. 3C are example schematics of divide-by-2 circuits with variable tail bias current sources.

FIG. 4 is an example diagram of phase alteration in a divide-by-2 circuit.

FIG. 5 is an example schematic of a low intermediate frequency (IF) radio.

FIG. 6 is an example schematic of a direct-conversion radio.

FIGS. 7 and 8 are examples of methods for tuning a phase difference.

### DETAILED DESCRIPTION

As described above, parasitic effects can degrade the phase accuracy of a quadrature LO and thereby adversely affect image rejection when the LO is used to drive an image-rejecting mixer circuit. While computer aided design tools can enable accurate modeling of some parasitic effects, certainty about the actual phase accuracy or image rejection that a particular system will achieve after manufacturing generally can not be guaranteed. Such parasitic effects can be described as falling into two categories. First, the parasitic effects can be random effects which vary from one sample of the system to another. Second, the parasitic effects can be systematic effects which are generally common to samples of the system. Calibration algorithms can be developed to compensate or tune out both random and systematic parasitic effects. For systems requiring less accuracy post-manufacturing, tuning may be used to compensate for systematic parasitic effects. Techniques are described below for adjusting the accuracy of quadrature LO signals compatible with, for example, systems using calibration algorithms or post-manufacturing tuning.

Doing so for a LO used in image rejection may help to improve the quality of the image rejection. In general, the following will describe tuning the phase of a frequency divider that generates quadrature LO signals for image rejection. However this is provided as an example. The techniques described below may be used in other circuits which require adjustment of phase.

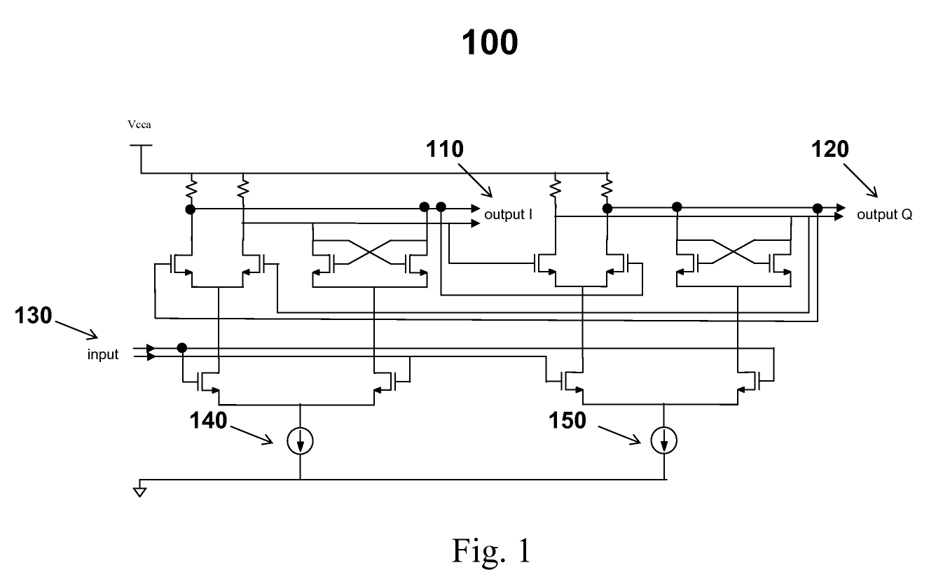

FIG. 1 is an example schematic of a divide-by-2 circuit 100 using Current-Mode Logic (CML) topology. In general, divide-by-two circuits can produce one output clock period for every two input clock periods. More complicated architectures which permit variable division or counting by using digital control signals to change an input clock signal's different dividing paths may also be used to include higher order dividers. For example, digitally changing a clock division path may permit the divide-by-two circuit to ignore or “pulse swallow” an additional clock pulse such that three input clock pulses are needed to generate one output clock signal (e.g., divide-by-three).

The divide-by-2 circuit 100 includes two branches coupled in a ring fashion such that each side is driven by the input signal 130. The left branch generates the I output signal 110 and the right branch generates the Q output signal 120. The input signal 130 phase is inverted between the inputs to the parts of the circuit that generate the I and Q output signals 110 and 120. Each side is biased by a separate, fixed tail current source 140 and 150.

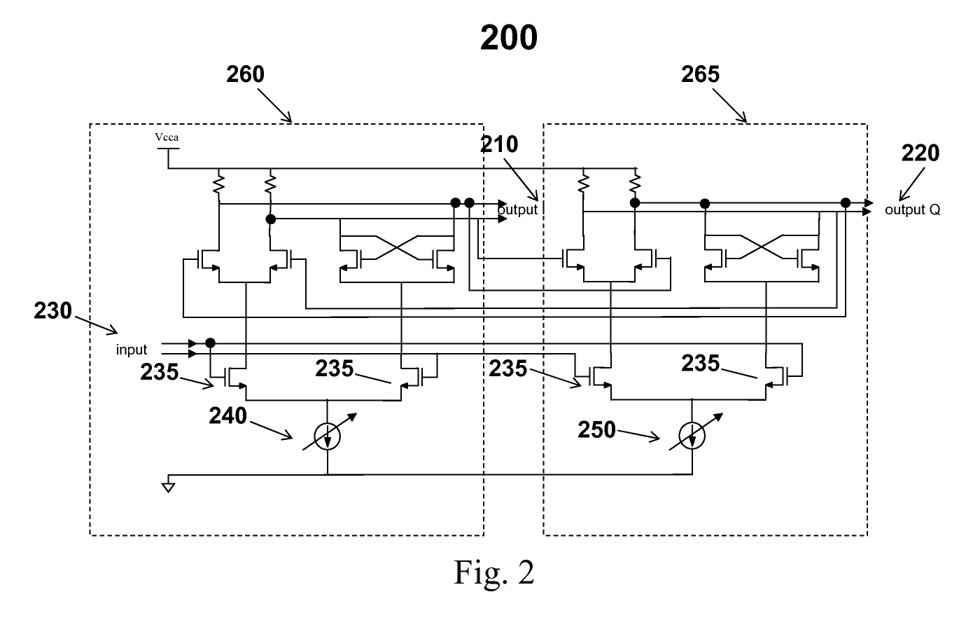

FIG. 2 is an example schematic of a divide-by-2 circuit 100 with variable tail bias current sources. The components of the divide-by-2 circuit 200 are generally similar to that of the circuit 100 of FIG. 1, except the separate tail current sources 140 and 150 have been replaced with variable bias current sources 210 and 220.

Due to the typically high frequency of RF frequency dividers, divider outputs may not be in the form of a square wave as the divider outputs may have rise and fall times that are substantial fractions of the cycle time. As such, the phase of the I and Q outputs 210 and 220 can be adjusted by modifying the tail bias current(s). More particularly, modifying the bias current can change the transconductance of the NMOS devices 235 that are connected to the input signal 230 or other NMOS devices. An increase in the bias current can cause the current commutation through these NMOS devices to be faster, therefore resulting in shorter rise and fall times of the output signal and an acceleration or reduction of the phase of the I and Q output signal 210 and 220.

For example, if the bias current on the I branch 260 of the circuit 200 is increased or decreased by varying the tail bias current 240, the phase of the I output signal 210 can be varied with respect to the Q output signal 220. Therefore, the phase difference between I output signal 210 and Q output signal 220 can be altered. Furthermore, if the bias current on the Q branch 265 of the circuit 200 is increased or decreased by varying the tail bias current 250, the phase of the Q output signal 220 can be varied with respect to the I signal. Therefore, the phase difference between the Q output signal 220 and I output signal 210 can be altered.

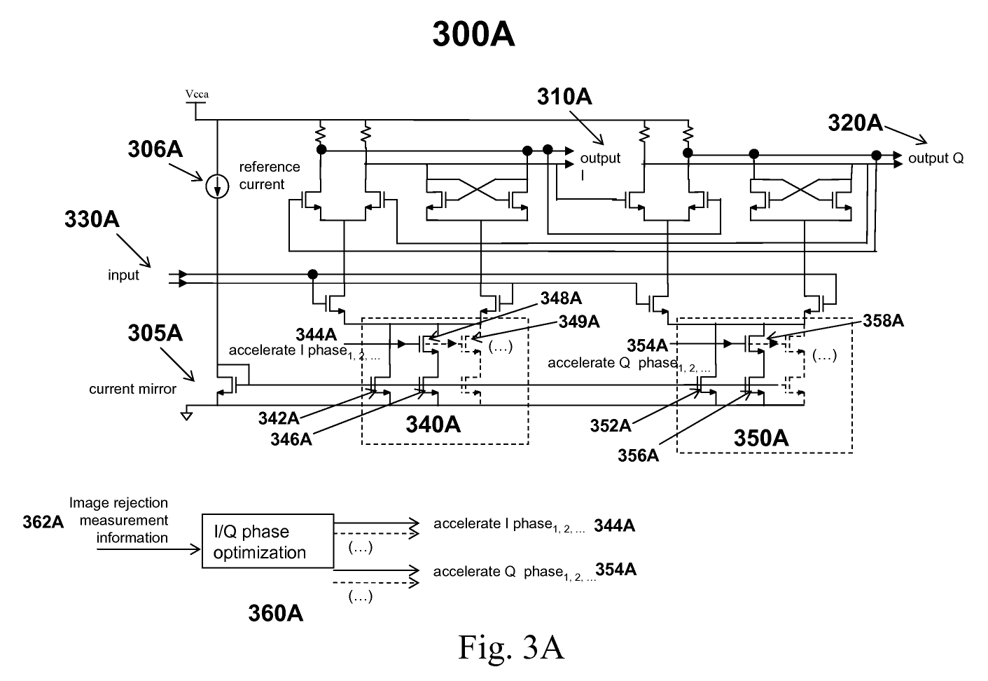

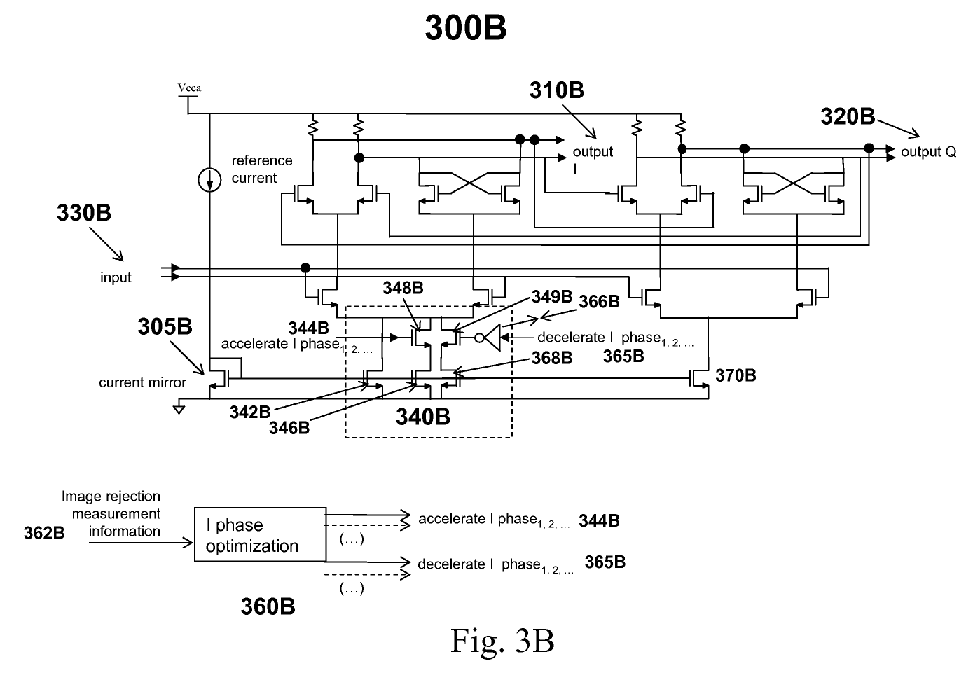

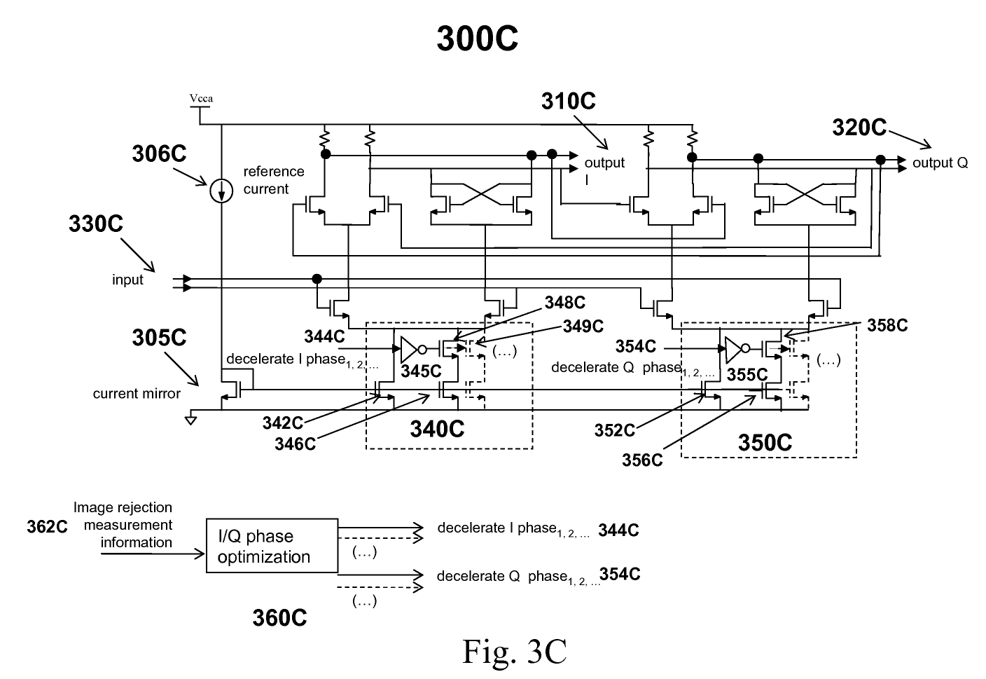

FIGS. 3A and 3B are example schematics showing an implementation of tail bias circuits to achieve a desired phase difference between I and Q outputs of a divide-by-2 circuit. More specifically, the circuit 300A of FIG. 3A is directed to accelerating either of the I and/or Q branches to achieve the desired phase difference, while the circuit 300B of FIG. 3B is directed to accelerating or decelerating a single branch to achieve the desired phase difference. The techniques of FIGS. 3A and 3B may be used alternatively or in combination.

Referring to FIG. 3A, circuit 300A includes variable tail bias currents 340A and 350A. The variable current sources 340A and 350A include multiple NMOS current sources driven with a current mirror circuit 305A biased by a reference current 306A to create I and Q output signals 310A and 320A from an input signal 330A. The variable current sources 340A and 350A can each include NMOS current source 342A and 352A and one or more additional NMOS current sources 346A and 356A. The variable current sources 340A and 350A can each include NMOS switching transistors connected in series with the additional NMOS current sources 346A and 356A. As a result, the additional NMOS current sources 346A and 356A can be switched on or off by applying accelerate I and Q phase signals 344A and 354A to the respective switching transistors 348A and 358A.

As shown, the variable current sources 340A and 350A of both the I and Q branches include additional NMOS current sources 346A and 356A, though various implementations can include one or more additional NMOS current sources 346A and 356A in only either the I branch or the Q branch. Also, although the current sources shown are NMOS current sources, other types of transistors or field effect devices can be used.

In various implementations, the additional NMOS current sources 346A and 356A have aspect ratios which are smaller, by a factor “x,” than the aspect ratio of the fixed current source 342A and 352A. For example, the current source 342A can have an aspect return of W/L while the additional current source 346A has an aspect ratio of W/(x*L) and W/(2*x*L). The ratio “x” can be determined based on the phase shift desired from the accelerate I and Q phase signals 344A and 354A. The additional NMOS current sources can include gradually smaller aspect ratios such that the phase can be tuned in several, increasingly precise, steps. For example, in one implementation additional current sources can have aspect ratios that scale by factors of 2, 4, 8, . . . , 2^{N-1} as compared to the first current source 342A or 352A. This can result in a binary weighted scaling and 2^{N} phase tuning steps with an equidistant step size.

The accelerate I and Q phase signals 344A and 354A can be controlled by an I/Q phase optimization control 360A. In particular, this control can include a calibration algorithm that successively measures the image rejection and generates the accelerate I and Q phase signals 344A and 354A to optimize the phase of the I and Q signals to improve the image rejection. In some implementations, the calibration algorithm can be an automatic procedure that is integrated into the system. In other implementations, the calibration algorithm can include a manual procedure carried out by an operator to measure the image rejection and manually switch the accelerate I and Q phase signals 344A and 354A to optimize the image rejection.

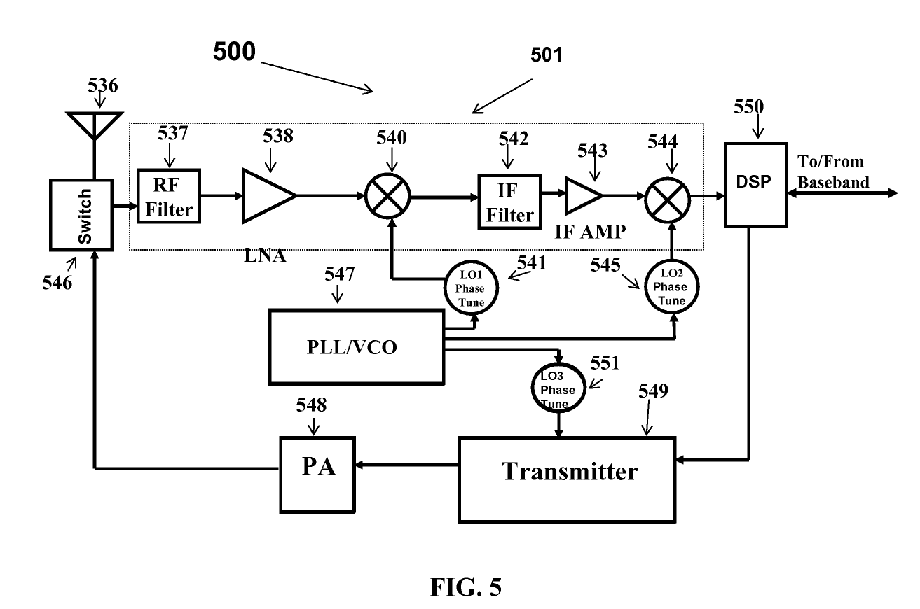

The input to the I/Q phase optimization control 360A is image rejection measurement information 362A. This input can be a measurement of the phase difference between the I and Q output signals 310A and 320A and can be, for example, from an output of the first mixer 540 of FIG. 5. Other implementations can directly input the I and Q output signals 310A and 320A to the I/Q phase optimization control 360A where the phase difference can be measured internally in the control of 360A.

The I/Q phase optimization control 360A determines the accelerate I and Q phase outputs 344A and 354A, based on the input image rejection measurement information 362A to obtain the desired I and Q phase difference. More specifically, the I/Q phase optimization control 360A determines whether a tail bias current in the I or Q branch should be altered to achieve a more desirable phase difference between the I and Q output signals 310A and 320A. For example, by switching on one or more additional NMOS current sources, the I/Q phase optimization control 360A can increase the tail bias current, and as explained above, accelerate the phase of the output associated with the tail bias current. As such, the I/Q phase optimization control 360A can be part of a signal feedback loop controlling the I and Q branches through consideration of the I and Q output signals 310A and 320A.

Moreover, the I/Q phase optimization control 360A can have multiple signals (or multiple bits of output) for either of the accelerate I phase or accelerate Q phase outputs 344A and 354A. In various implementations, each bit within an output signal can be coupled to a specific current source within each variable current sources 340A and 350A. For example, as shown in FIG. 3A, the I variable current source 340A includes two additional NMOS current source 346A and 349A, which each may be controlled by a bit of an output of the accelerate I phase output 344A of the I/Q optimization control 360A so as to be selectively switched on or off depending on the bit values.

The I/Q phase optimization control 360A can incorporate hardware, digital processing, or both, depending on the desired sophistication and level of control. In some implementations, the I/Q phase optimization control 360A can include a phase comparator and logic circuitry to determine the desired output signals. In other implementations, the I/Q phase optimization control 360A can incorporate an arithmetic logic unit (ALU), along with or instead of comparator and logic circuitry, to determine the desired output signals.

Referring to FIG. 3B, circuit 300B includes dual variation of a single tail bias current source. Variable current source 340B and current source 370B include NMOS current sources driven with a current mirror circuit 305B to create I and Q output signals 3108 and 3208 from an input signal 330B. The variable current source 3408 can include an NMOS current source 342B, and one or more additional NMOS current sources 346B and 368B. The variable current source 340B can include NMOS switching transistors 348B and 349B connected in series with the additional NMOS current sources 346B and 356B. The switching transistors 348B and 349B are coupled to an accelerate phase signal 344B and an inverted decelerate phase signal 365B by an inverter 366B (or bits thereof), respectively.

The switching transistor 349B coupled to the decelerate phase signal 365B is generally switched on during normal operation. As such, during normal operation, the tail bias current can include a current level that incorporates the current draw of the NMOS current source 342B and the additional NMOS current source 368B. The current flow of the additional NMOS current sources 346B and 368B can be altered by switching the switched on or off the switching transistor 348B and 349B using the one or more accelerate phase signals 344B and 365B. Also, although the current sources are shown as NMOS current sources, other types of transistors or field effect devices can be used.

Although only a single additional NMOS current source is shown for each of the accelerate and decelerate phase signals 344B and 365B, multiple additional NMOS current sources may be included for more precise control. In various implementations, the additional NMOS current sources 346B and 348B have an aspect ratio that is smaller, by a factor “x,” than the aspect ratio of the fixed current source. For example, the current source 346A can have an aspect return of W/L while additional current sources (not shown) can have an aspect ratio of W/(x*L). The ratio “x” can be determined based on the phase shift desired to result from the accelerate phase signal 344B and decelerate phase signal 365B.

The accelerate phase signal 344B and decelerate phase signal 364B can be controlled by an I phase optimization control 360B. In particular, this control can include a calibration algorithm that successively measures the image rejection and generates the accelerate phase signals 344B and 365 to optimize the phase of the I and Q signals such that the image rejection is improved. In one implementation, the calibration algorithm can be an automatic procedure that is integrated into the system. In other implementations, the calibration algorithm can include a manual procedure carried out by an operator to measure the image rejection and manually switch the accelerate phase signals to optimize the image rejection.

The input to the I phase optimization control 360B is the image rejection measurement information 362B. This input can be a measurement of the phase difference between the I and Q output signals 310B and 320B and can be, for example, from an output of the first mixer 540 of FIG. 5. Other implementations may directly input the I and Q output signals 310B and 320B to the I phase optimization control 360B where the phase difference is measured internally in the control of 360B. Other implementation may measure the image rejection in the digital signal processing unit (DSP) 550 shown in FIG. 5.

The I phase optimization control 360B determines the accelerate I phase 344B and decelerate I phase outputs 365B, based on the input image rejection measurement information 362B, so as to obtain the desired I and Q phase difference. More specifically, the I/Q phase optimization control 360B can determine whether the tail bias current in the I branch should be increased or decreased to achieve a more desirable phase difference between the I and Q output signals 310B and 320B. For example, by switching on the additional NMOS current source 346B which is normally switched off, the I phase optimization control 360B can increase the tail bias current, and as explained above, accelerate the phase of the I output signal. Moreover, by switching off the additional NMOS current source 368B which is normally switched on, the I/Q phase optimization control 360B can decrease the tail bias current, and as explained above, decelerate the phase of the I output signal As such, the I/Q phase optimization control 360B can be part of a signal feedback loop controlling the I and Q branches through consideration of the I and Q output signals 310B and 320B.

Moreover, the I phase optimization control 360A or 360B may have multiple signals (or multiple bits of output) for either of the accelerate I phase or decelerate I phase outputs. In various implementations, each bit within an output signal is tied to a specific current source within the variable bias current source. For example, as shown in FIG. 3A, the variable current source 340A includes two switching transistor 348B and 349B. Each of the NMOS switching transistors 348 and 349B can be tied to a bit of an output of the accelerate I phase 344A or the decelerate I phase output 368A, respectively, of the I/Q optimization control 360A.

The I phase optimization control 360B can incorporate hardware, digital processing, or both, depending on the desired sophistication and level of control. In one implementation, the I phase optimization control 360B includes phase comparator and logic circuitry to determine the desired output signals. In other implementations, the I phase optimization control 360B can incorporate an ALU, along with or instead of comparator and logic circuitry, to determine the desired output signals.

Although the circuit 300B of FIG. 3B includes only one variable current source with the accelerate I phase 344A and the decelerate I phase output 368A, other implementations may use more variable current sources. For example, the techniques of using first and second variable current sources as shown in the circuit 300A of FIG. 3A can be used in conjunction with the techniques of using both an accelerate and decelerate signals as shown in the circuit 300B of FIG. 3B. As such, in various implementation, each of a first and second variable current source can include an accelerate and a decelerate signal. This can enable more precise tuning and control options to be employed by phase optimization circuitry.

Although the circuit 300A of FIG. 3A is directed to I phase and Q phase accelerating to tune phase difference of the frequency divider output signals, other implementations may similarly tune an output through the use of decelerating the I phase and Q phase outputs. The circuit 300C of FIG. 3C is an example of such an implementation, which includes decelerating the I phase and decelerating Q phase outputs 310C and 320C to tune the phase difference of the frequency divider output signals by decreasing the tail current of the variable current sources 340C and 350C. That is, the circuit 300C of FIG. 3C is similar to the functioning of the circuit 300A although the variable current sources 340C and 350C are decreased to adjust phase rather than increased. As discussed above, adjusting phase through decreasing current can be conducted, for example, by switching off additional NMOS current sources 346C or 356C which are normally on.

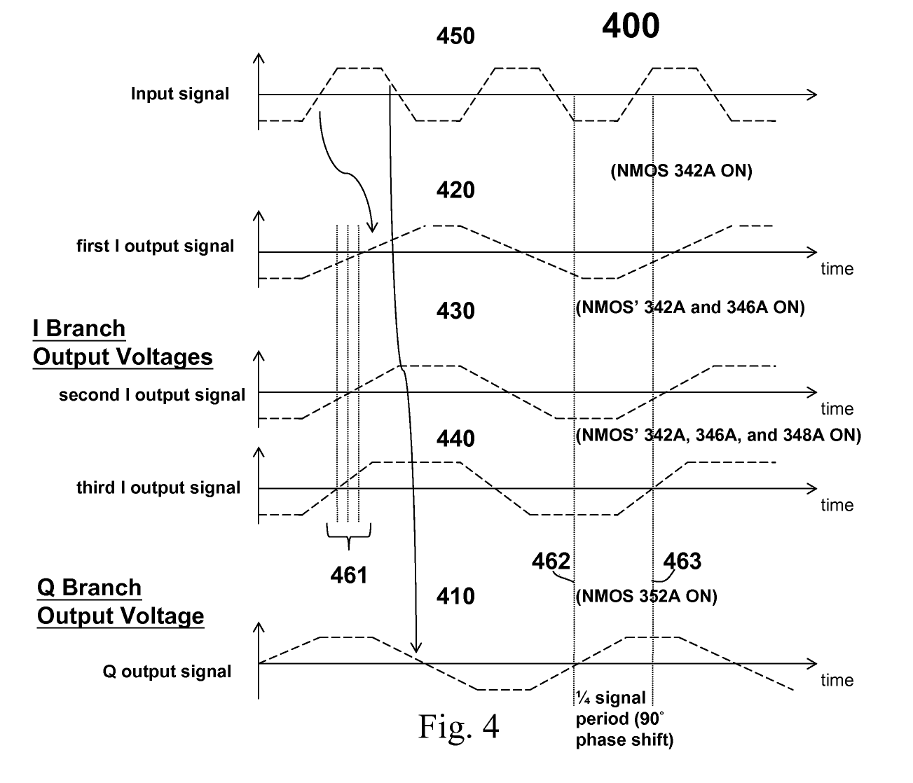

FIG. 4 is an example timing diagram 400 of phase alteration in the I branch of a divide-by-2 circuit with variable tail bias current sources. The timing diagram 400 illustrates varying phases between I and Q branches that can be generated with, for example, the divide-by-2 circuits 300A or 300B of FIG. 3A or 3B, respectively. For simplicity of understanding, FIG. 4. is directed to the NMOS current sources of FIG. 3A. Nevertheless, the accelerate and decelerate functions of NMOS current sources of FIG. 3B could also be used to effect the phase (through acceleration or deceleration) similar to the phase alteration shown in the timing diagram 400 of FIG. 4. In particular, the timing diagram compares three waveforms of the I output signal with the Q output signal.

In this example, optimal image rejection performance can require that the phase difference between the I output signal and the Q output signal be near 90°. This can correspond to a situation in which the difference between the times of zero crossing for the rising edge of the Q output signal and that of the rising edge of the I output signal equal one quarter of the period of either output signal. As can be seen in the timing diagram 400, the time difference between the rising edge of the Q output signal 410 and that of the first I output signal 420 is different than the optimal time indicated by the pair of lines 462 and 463. More particularly, in the example of FIG. 4, the time difference between the rising edge of the Q output signal 410 and that of the first I output signal 420 is smaller than 90°. Such a situation can occur due to mismatches in the divide-by-2 circuit or mismatches in the I and Q branches of the circuits connected to the outputs of the divide-by-2 circuit.

The Q output signal 410 is generated with, for example, the variable current source 350A of FIG. 3A or a non-variable current source 150 of FIG. 1. The Q output signal 410 has a rise time related to the angle (or dI/dt) of the signal's rise/fall. Ideally, the Q output signal 410 is out of phase with the I output signal 420-450 by 90 degrees. The first I output signal 420 is generated with, for example, the NMOS current source 342A of the variable current source 340A of FIG. 3A. As can be seen by the timing diagram 400, the first I output signal 420 does not have a 90 degree phase difference as compared to the Q output signal 410. This error may be due to parasitic errors as described above.

The timing diagram 400 also shows a timing of an input signal 450. Each rising edge of the input signal 450 can cause a rising or falling edge of the I output signal and each falling edge of the input signal 450 can cause a rising or falling edge of the Q output signal. Therefore, the timing and phase difference of the I and Q output signals can depend on the duty cycle of the input signal 450. Consequently, a situation of non-optimal phase between the I and Q output signals (i.e., significantly different than 90°) can also be caused by a non-optimal duty cycle of the input signal 450.

In order to compensate for the phase difference between the first I output signal 420 and the Q output signal 410, the additional NMOS current source 346A can be switched on with the accelerate phase signal 344A to generate the second I output signal 430. The additional NMOS current source 346A increases transconductance of the NMOS devices which are also connected to the input signal 330A, and, thus, decreases the rise and fall time of the I output signal as illustrated by the second I output signal 430. The phase difference between the second I output signal 430 and the Q output signal has been improved, but still includes significant error. By switching on a second additional current source, the transconductance is further increased and the third I output signal 440 is generated. The third I output signal 440 is nearly 90 degrees out of phase with the Q output signal 410. As can be seen from the group of lines 461 indicating various positions of the zero crossing time of the I output signal, switching in a first and then a second additional NMOS current source can enable multiple different levels of phase tuning between the I and Q output signals.

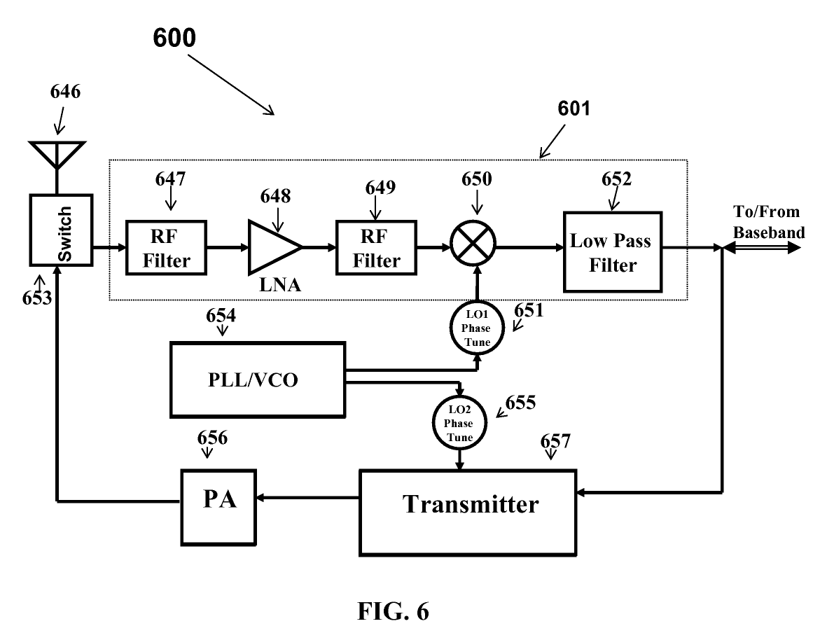

The disclosed techniques can be used with wireless communication systems. For example, the disclosed techniques can be used with receivers, transmitters, and transceivers, such as the receiver, transmitter, and/or transceiver architectures for superheterodyne receivers, image-rejection (e.g., Hartley, Weaver) receivers, zero-intermediate frequency (IF) receivers, low-IF receivers, direct-up transceivers, two-step up transceivers, and other types of receivers and transceivers for wireless and wireline technologies. FIGS. 5 and 6 are schematics demonstrating two examples of systems in which the techniques described above can be used.

In particular, FIG. 5 is a schematic of a low IF radio 500. One or more phase-locked loop (PLL) circuits 547 including one or more voltage controlled oscillators can generate local oscillator signals to be phase shifted and tuned by circuits 541, 545 and 551 to be used in the radio 500. For the receiver 501 path, an RF signal arriving at an antenna 536 passes through a switch 546, a RF filter 537, a low noise amplifier (LNA) 538, and into the first mixer 540, which performs image rejection and down converts the RF signal to a low frequency intermediate frequency by mixing it with the signal produced by the first LO phase shifter and tuner 541. The undesired mixer products in the IF signal are rejected by an IF filter 542. The filtered IF signal then enters an IF amplifier stage 543, after which the outputs feeds into the second mixer 544 that translates it down to yet another intermediate frequency by mixing it with the signal produced by a second LO phase shifter and tuner 545. The signal is then sent to a DSP 550 with analog-to-digital(A/D) and digital-to-analog (D/A) functions for digital signal processing before being sent to the baseband for further processing. Tuning into a particular channel within the band-limited RF signal is accomplished by varying the frequency of each LO.

For the transmission path, a signal is sent to the transmitter 549 from the baseband through the DSP 550. The transmitter 549 modulates, mixes and up converts the signal by using a third LO phase shifter and tuner 551. The phase tuning techniques described above can be used to tune the I and Q phase difference of the LO phase shifter and tuner 551. The signal is then input to a power amplifier (PA) 548 to be amplified and passed through the switch 546 to the antenna 536 for transmission. Moreover, one or more of the mixers 540 or 544, the LO phase shifters 541, 545 and 551, or the demodulator in the receiver 501 or the modulator in the transmitter 549 can use the phase tuning techniques described above.

In another example, FIG. 6 is a schematic of a direct-conversion radio 600. One or more phase-locked loop (PLL) circuits 654 including one or more voltage controlled oscillators can generate local oscillator signals to be processed by phase shifter and tuners 651 and 655 to be used in the radio 600. An antenna 646 couples a RF signal through a first bandpass RF filter 647 into an LNA 648. The signal then proceeds through a switch 653, to a second RF filter 649. The second RF filter 649 yields a band-limited RF signal, which then enters a mixer 650 and mixes with an LO frequency produced by an LO phase shifter and tuner 651. The LO phase shifter and tuner 651 can use the phase tuning techniques described above. The mixer 650 output is coupled into a lowpass analog filter 652 before proceeding into baseband information signal for use by the remainder of the communications system.

For the transmitter path, a signal is sent to the transmitter 657 from the baseband. The transmitter 657 modulates, mixes, and up-converts the signal by using a second LO phase shifter and tuner 655. The phase tuning techniques described above can be used to tune the I and Q phase difference of the LO. The signal is then input to a PA 656 to be amplified and passed through the switch 653 to the antenna 646 for transmission. One or more of the mixers 650, the LOs generated by the PLL 651 and 655, the demodulator in the receiver 601, or the modulator in the transmitter 657 can use the phase tuning techniques described above.

Various topologies for circuit models can also be used. The exemplary designs shown are not limited to any particular process technology, and can use various process technologies, such as CMOS or BiCMOS (Bipolar-CMOS) process technology, or Silicon Germanium (SiGe) technology. The circuits can be single-ended or fully-differential circuits.

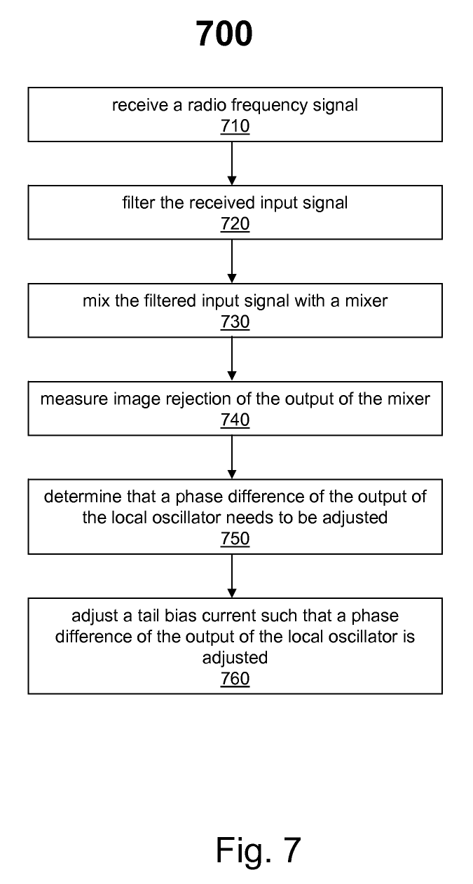

FIG. 7 is a method 700 for tuning the phase of, for example, an output of a local oscillator within a circuit system. The method 700 can be used, for example, in conjunction with the schematics 200-300B of FIGS. 2, 3A, and 3B along with or separate from the receivers 500 and 600 of FIGS. 5 and 6. For simplicity of understanding, the method 700 will be described with respect to the direct-conversion receiver 600 of FIG. 6.

Initially, a radio frequency signal is received (710). The signal may be received as input to an antenna of a cellular phone or other mobile device. After being received at the antenna, the signal may be input to one or more circuit components, such as, for example, an amplifier. The received input filter is filtered (720). The filter may be, for example, the bandpass RF filter 647 of FIG. 6. The filtered input signal is then mixed with a mixer circuit (730). The image rejection of the output of the mixer is measured (740). For example, referring to the schematic 600 of FIG. 6, the electrical connection between the mixer 650 and the low pass filter 652 can be measured to determine a level of image rejection of signal mixing of the mixer 650.

Based on the measured image rejection of the output of the mixer, it is determined that a phase difference of the output of the local oscillator needs to be adjusted (750). For example, the measured image rejection of a mixer can be processed by a control circuit to determine whether the image rejection is within acceptable limits. As such, if the image rejection is determine to be unacceptable, such as above a threshold magnitude (e.g., a decibel value), the control circuit can determine to adjust the phase difference. Finally, a tail bias current is adjusted such that a phase difference of the output of the local oscillator is adjusted (760). In one implementation, the tail bias current is generated by one or more transistors within the local oscillator 651. Moreover, the control circuit may switch the one or more transistors through one or more bits output by the control circuit.

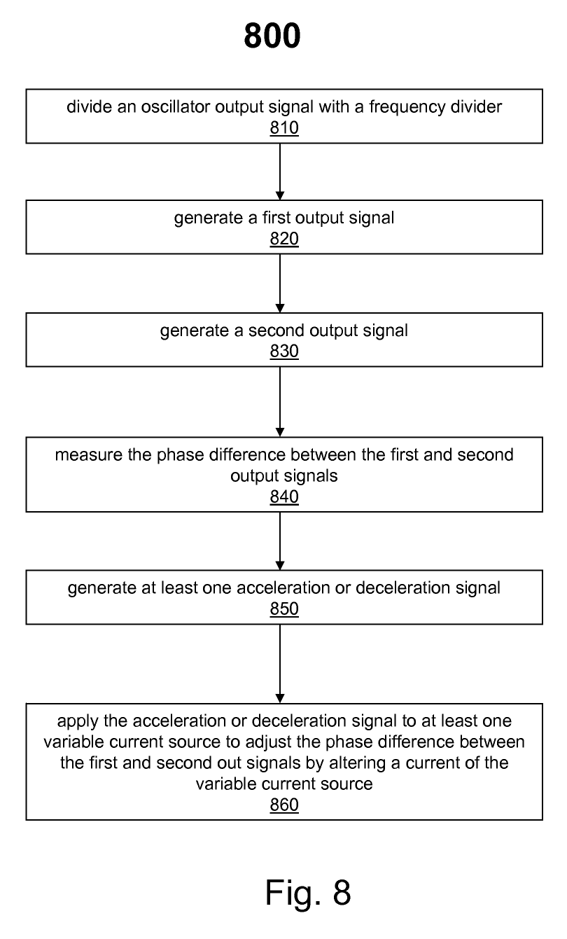

FIG. 8 is a method 800 for tuning phase within a frequency divider or other circuitry. The method 800 can be used, for example, in conjunction with the schematics 200-300B of FIGS. 2, 3A, and 3B along with or separate from the receivers 500 and 600 of FIGS. 5 and 6. For simplicity of understanding, the method 800 will be described with respect to the schematic 300B of FIG. 3B.

In the method 800, an oscillator output signal is divided with the frequency divider (810). Also, first and second output signals are generated (820 and 830). In particular, a differential frequency divider can be used to generate an I output and a Q output signal by dividing the oscillator output signal. For example, the input signal may be received at the input 330B and maybe divided to an I branch output 310B and a Q branch output 320B.

The phase difference between the first and second output signals is measured (840). In various implementations, an I output signal and a Q output signal are measured to, for example, determine whether a phase difference is outside of a target magnitude. The measurement may be based on a sampling of the I branch output 310B and a Q branch output 320B and may involve other comparison or measuring circuitry. The measurement may be input as the image rejection measurement information 362B input to the I phase optimization control 360B.

Next, at least one acceleration or deceleration signal is generated (850). For example, it may be determined that the phase difference between the I output signal and a Q output signal is outside of a target magnitude, and based on this determination, the acceleration or deceleration signal may be generated. Various implementations may use the I phase optimization circuit 360B to create the acceleration or deceleration signal if a measured image rejection is not within acceptable limits (i.e., a decibel range).

Finally, the acceleration or deceleration signal is applied to at least one variable current source to adjust the phase difference between the first and second out signals by altering a current of the variable current source (860). In particular, a current of a variable current source coupled to the differential frequency divider can be increased or decreased such that the phase difference between the I output signal is increased or decreased, using, for example, an accelerate or decelerate output 344B or 365B of the I is phase optimization circuit 360B. As described above, increasing or decreasing a tail current can increase or decrease the rise or fall time of the I output signal. Altering the rise or fall time can, in turn, alter the phase difference between the I output signal and the Q output signal.

The systems and methods can include use of other components. Some of the components can include computers, processors, clocks, radios, signal generators, counters, test and measurement equipment, function generators, oscilloscopes, phase-locked loops, frequency synthesizers, phones, wireless communication devices, and components for the production and transmission of audio, video, and other data. Some particular implementations have been described in this disclosure. Other implementations are within the scope of the following claims.

1. A method comprising:
coupling a differential input signal to first and second input terminals of a differential frequency divider, the differential frequency divider including at least a first variable current source;
coupling a first output signal connected to a first output terminal of the differential frequency divider to a third input terminal of the differential frequency divider;
coupling a second output signal connected to a second output terminal of the differential frequency divider to a fourth input terminal of the differential frequency divider; and
coupling an input terminal of the first variable current source to phase optimization circuitry that is configured to adjust the first variable current source such that a phase difference between first and second output signals of the differential frequency divider is adjusted.

2. The method of claim 1 wherein the first output signal is an in-phase output signal and the second output signal is a quadrature output signal or the first output signal is quadrature output signal and the second output signal is an in-phase output signal.

3. The method of claim 1 wherein coupling the first variable current source to the phase optimization circuitry includes coupling the first variable current source to the phase optimization circuitry such that the rise or fall time of the first output signal is altered by altering a current of the first variable current source.

4. The method of claim 3 wherein the first variable current source includes one or more transistors or field effect devices that are switched on or off to alter the current of the first variable current source.

5. The method of claim 1 wherein the differential frequency divider includes a second variable current source, the method further comprising:
coupling the second variable current source to the phase optimization circuitry such that the rise or fall time of the second output signal is altered by altering a current of the second variable current source.

6. The method of claim 5 wherein the phase optimization circuitry is configured to adjust the first and second variable current sources by altering currents of the first and the second current sources separately or in combination.

7. The method of claim 5 wherein the second variable current source includes one or more transistors or field effect devices that are switched on or off to alter the second variable current source.

8. The method of claim 5 further comprising:
coupling a current mirror to the first and second variable current sources; and
coupling a reference bias current to the current mirror to generate tail bias current sources for tuning the phase differences between the first and second output signals.

9. The method of claim 5 wherein each of the first and the second variable current sources include a fixed tail bias current source and multiple switching tail bias current

10. The method of claim 5 wherein each of the variable current sources includes an accelerating input or each of the variable current sources includes a decelerating input.

11. The method of claim 10 wherein the accelerating or decelerating inputs are controlled by the phase optimization circuitry based on the first output signal and the second output signal.

12. The method of claim 11 wherein the phase optimization circuitry is configured to adjust the accelerating input and the decelerating input based on the first output signal and the second output signal of the frequency divider.

13. The method of claim 5 wherein at least one of the variable current sources includes an accelerating input and a decelerating input.

14. The method of claim 1 wherein the first variable current source includes an accelerating input and a decelerating input.

15. The method of claim 1 wherein coupling the input terminal to the phase optimization circuitry includes coupling phase optimization circuitry configured to increase current of the first variable current source.

16. The method of claim 1 wherein coupling the input terminal to the phase optimization circuitry includes coupling phase optimization circuitry configured to decrease current of the first variable current source.

17. The method of claim 1 wherein the differential frequency divider includes a third or higher order divider.

18. The method of claim 1 wherein coupling the input terminal to the phase optimization circuitry includes coupling phase optimization circuitry configured to enable tuning of a quadrature phase difference for a quadrature local oscillator signal between the first output signal and the second output signal by adjusting the first variable current source.

19. The method of claim 1 further comprising coupling phase tuning information associated with the first and second output terminals of the differential frequency divider to the phase optimization circuitry.

20. The method of claim 19 wherein coupling phase tuning information to the phase optimization circuitry includes coupling image rejection information to the phase optimization circuitry.

21. The method of claim 19 wherein coupling phase tuning information to the phase optimization circuitry consists of coupling the first and second output terminals to the phase optimization circuitry.

22. A differential frequency divider circuit comprising:
first and second input terminals each configured to receive a differential input signal;
a first output terminal configured to produce a first output signal;
a second output terminal configured to produce a second output signal;
a third input terminal coupled to the first output terminal;
a fourth input terminal coupled to the second output terminal; and
a first variable current source, wherein altering a current of the first variable current source causes a change in the phase difference between a first output signal of the first output terminal and a second output signal of the second output terminal.

23. The circuit of claim 22 wherein the first output signal is an in-phase output signal and the second output signal is a quadrature output signal.

24. The circuit of claim 22 wherein the first output signal is quadrature output signal and the second output signal is an in-phase output signal.

25. The circuit of claim 22 further comprising phase optimization circuitry, coupled to the first variable current source, configured to tune a phase difference between the first output signal and the second output signal by altering the current of the first variable current source.

26. The circuit of claim 25 further comprising:
a second variable current source, wherein the phase optimization circuitry is configured to tune a phase difference between the first output signal and the second output signal by altering both the currents of the first variable current source and the current of the second variable current source.

27. The circuit of claim 25 wherein the phase optimization circuitry is configured to tune a phase difference between the first and second output signals by altering currents of the first and the second current sources separately or in combination.

28. The circuit of claim 26 wherein the phase optimization circuitry is configured to tune the phase difference based on a measurement of image rejection.

29. The circuit of claim 26 further comprising:
a current mirror coupled to the first and second variable current sources; and
a reference bias current coupled to the current mirror to generate tail bias current sources for tuning the phase differences between the first and the second output signals.

30. The circuit of claim 26 wherein the phase optimization circuitry is further configured to increase or decrease the current of the first variable current source by switching one or more transistors or field effect devices on and off.

31. The circuit of claim 26 wherein each of the first and the second variable current sources include a fixed tail bias current source and multiple switched tail bias current sources, wherein each switched tail bias current source is weighted to provide a different amount of current.

32. The circuit of claim 31 wherein the phase optimization circuitry includes an output coupled to each of the multiple switched tail bias current sources to selectively switch the corresponding switched tail bias current source on and off.

33. The circuit of claim 26 wherein each of the variable current sources includes an accelerating input or each of the variable current sources includes a decelerating input.

34. The circuit of claim 33 wherein at least one of the variable current sources includes an accelerating input and a decelerating input.

35. The circuit of claim 33 wherein the phase optimization circuitry is configured to adjust the accelerating input and the decelerating input based on an in-phase I output signal or a quadrature-phase Q output signal.

36. The circuit of claim 22 wherein the differential frequency divider includes a third or higher order divider.

37. The circuit of claim 22 further comprising phase optimization circuitry configured to adjust the first variable current source such that a phase difference between the first and second output signals is adjusted.

38. The circuit of claim 37 wherein the phase optimization circuitry is coupled to phase tuning information associated with the first and second output terminals.

39. The circuit of claim 38 wherein the phase tuning information consists of signals of the first and second output terminals.

40. The circuit of claim 38 wherein the phase tuning information includes image rejection information.

41. The circuit of claim 22 wherein the first variable current source includes an accelerating input and a decelerating input.

42. A method of tuning a phase comprising:
dividing an oscillator output signal with a frequency divider;
generating a first output signal of the frequency divider;
generating a second output signal of the frequency divider with a phase different from the first output;
measuring the phase difference between the first and the second output signals of the frequency divider;
generating, based on the measured phase difference between the first and the second output signals, at least one acceleration or deceleration signals; and
applying the acceleration or deceleration signal to at least one variable current source in the frequency divider to adjust the phase difference between the first and the second output signals by altering a current of the variable current source.

43. A method of tuning a phase, the method comprising:
receiving, as an input signal at an antenna, a radio frequency signal;
filtering the received input signal;
mixing the filtered input signal with a mixer coupled to phase shifted local oscillator output signals;
measuring image rejection of the phase shifted outputs of the mixer;
determining, based on the measured image rejection of the phase shifted outputs of the mixer, to adjust a phase difference of the output signals of the local oscillator; and
adjusting a tail bias current such that a phase difference of the output signals of the local oscillator, thereby adjusting the outputs of the mixer.

44. The method of claim 43 wherein adjusting the tail bias current includes increasing a tail bias current from a previous current level.

45. The method of claim 43 wherein adjusting the tail bias current includes decreasing a tail bias current from a previous current level.

46. The method of claim 43 wherein adjusting the tail bias current includes adjusting a tail bias current coupled to an I branch of the local oscillator and adjusting a tail bias current coupled to a Q branch of the local oscillator.

47. The method of claim 43 further comprising measuring the image rejection in the digital-signal-processor or in the baseband.

48. A method comprising:
dividing an input signal with at least one differential frequency divider to generate an I output signal and a Q output signal;
measuring a phase difference between the I and Q output signals of the differential frequency divider;
determining, based on the measured phase difference, that the phase difference between the I output signal and a Q output signal is outside of a target magnitude; and
increasing or decreasing a tail current of a variable current source coupled to the differential frequency divider such that the phase difference between the I and the Q output signal is decreased or increased.

49. A system comprising:
at least one phase-locked loop generating one or more local oscillators with different frequencies;
one or more phase shifting and tuning frequency dividers configured to generate quadrature phase shifted and tuned I/Q output signals from the local oscillator outputs;
a phase optimization circuit configured to tune the phase difference of phase shifted output signals based on feedback of output signals of the frequency divider;
a radio frequency (RF) input signal received by an antenna coupled to an RF filter;
an low noise amplifier (LNA) coupled to an output of the RF filter;
a first set of I/Q mixers configured to perform image rejection and mix an output of the LNA with a first set of quadrature I/Q output signals tuned by a first frequency divider from an output of a first local oscillator;
a set of I/Q IF filters coupled to a first set of mixed I/Q outputs of the first set of I/Q mixers;
a second set of I/Q mixers configured to mix filtered I/Q outputs of the I/Q intermediate filer (IF) filters with a second set of I/Q outputs generated and tuned by a second frequency divider from an output of a second local oscillator;
a second set of mixed I/Q outputs coupled to a digital-signal-processor; and a digital-signal-processed output coupled to a baseband for further processing.
